(19) United States
(12) Patent Application Publication
(10) Pub. No.: US 2014/0153318 A1
(43) Pub. Date: Jun. 5, 2014

(54) CIRCUIT AND METHOD FOR READING A RESISTIVE SWITCHING DEVICE IN AN ARRAY

(71) Applicant: Frederick Perner, Santa Barbara, CA (US)

(72) Inventor: Frederick Perner, Santa Barbara, CA (US)

(21) Appl. No.: 14/232,808

(22) PCT Filed: Jul. 22, 2011
(86) PCT No.: PCT/US2011/044967

§ 371 Date: Jan. 14, 2014

(51) Int. Cl. G11C 13/00

(52) U.S. Cl. CPC G11C 13/004; G11C 13/0002
USPC 365/148

(57) ABSTRACT

A read circuit for sensing a resistance state of a resistive switching device in a crosspoint array utilizes an equipotential preamplifier connected to a selected column line of the resistive switching device in the array. The equipotential preamplifier delivers a sense current while maintaining the selected column line at a reference voltage near a biasing voltage applied to unselected row lines of the array. The read circuit has a reference current source for generating a sense reference current, and a current comparator connected to evaluate the sense current delivered by the equipotential preamplifier against the sense reference current and generating an output signal indicative of the resistance state of the resistive switching device.

### BACKGROUND

Memristive devices, or memristors, are a new type of switching devices with an electrically switchable device resistance. Memristive devices are both scientifically and technically interesting, and hold promise for non-volatile memory (NVM) and other fields. With today's flash memory technology reaching its scaling limit, there is an urgent need for new memory technologies that can meet the storage capacity and speed demanded by future applications. Memories using resistive switching devices, such as memristors, are a promising candidate for meeting that need. For NVM applications, many nanoscale resistive switching devices can be formed in a two-dimensional array, such as a crossbar structure, to provide a very high storage capacity. Nevertheless, it has been a major challenge to reliably read the resistance state of a selected resistive switching device in an array, due that existence of other switching devices in the array that may form paths for leakage current, which can significantly reduce the signal/noise ratio of the read operation.

### BRIEF DESCRIPTION OF THE DRAWINGS

FIG. 1 is a schematic cross-sectional view of an example of a memristive device as one type of resistive switching device;

FIG. 2 is a schematic view of a crossbar structure containing multiple resistive switching devices;

FIG. 3 is a schematic diagram representing an abstraction of a crossbar of resistive switching devices;

FIG. 4 is a schematic diagram of an electronic circuit for reading a selected resistive switching device in a crossbar using an “equipotential sensing” circuit;

FIG. 5 is a flowchart showing a process of reading a selected resistive switching device in a crossbar using the circuit of FIG. 4; and

FIG. 6 is a schematic diagram of an implementation of the electronic circuit of FIG. 4 for reading a selected resistive switching device in a crossbar.

### DETAILED DESCRIPTION

The following description provides a circuit for reading the resistance state of a resistive switching device in an array of switching devices, and a corresponding method for performing the read operation. In some embodiments, the reading circuit may provide a digital output to represent the resistance state of switching device. For instance, a digital “0” may indicate that the device is in a high resistance state, or an “OFF” state, while a digital “1” may indicate that the device is in a low resistance state, or an “ON” state.

In some embodiments, the resistive switching device may be a bipolar memristive device (or memristor). As used herein, a memristive device is a switching device with its resistance representing its switching state, and the resistance depends on the history of the voltage and current applied to the device. The term “bipolar” means that the device can be switched from a low-resistance state (“LRS”) to a high-resistance state (“HRS”) by applying a switching voltage of one polarity, and from a high-resistance state to a low-resistance state by applying a switching voltage of the opposite polarity.

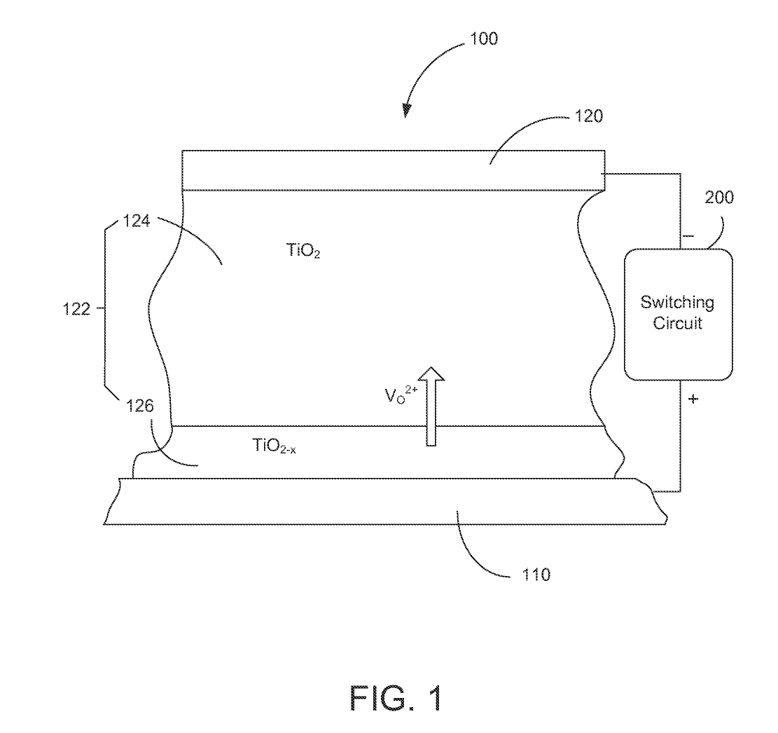

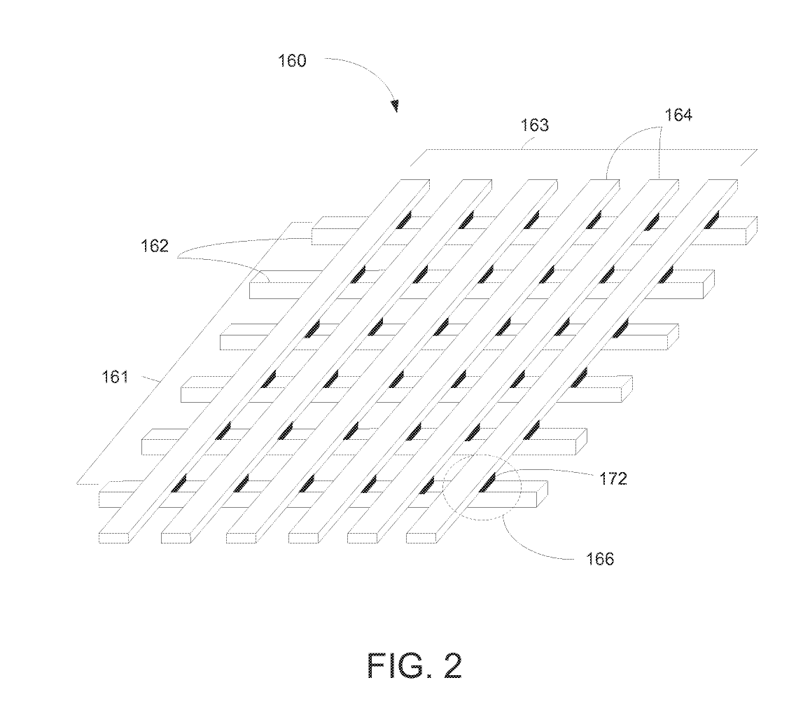

FIG. 1 shows, in a schematic form, an example of a bipolar memristive device 100. In the embodiment shown in FIG. 1, the memristive device is a two-terminal device, with a top electrode 120 and a bottom electrode 110. An active region 122, where the switching behavior takes place, is disposed between the two electrodes. The active region 122 of the switching device 100 includes a switching material that may be electronically semiconducting or nominally insulating, as well as a weak ionic conductor. The switching material contains dopants that may be driven under a sufficiently strong electric field to drift through the switching material, resulting in changes in the resistance of the memristive device. The memristive device 100 can be used, for example, as a non-volatile memory cell, for storing digital information. Such a memory cell may be incorporated into a crossbar structure to provide a high storage capacity, as illustrated in FIG. 2.

Many different materials with their respective suitable dopants can be used as the switching material. Materials that exhibit suitable properties for switching include oxides, sulfides, selenides, nitrides, carbides, phosphides, arsenides, chlorides, and bromides of transition and rare earth metals. Suitable switching materials also include elemental semiconductors such as Si and Ge, and compound semiconductors such as III-V and II-VI compound semiconductors. The listing of possible switching materials is not exhaustive and do not restrict the scope of the present invention. The dopant species used to alter the electrical properties of the switching material depends on the particular type of switching material chosen, and may be cations, anions or vacancies, or impurities as electron donors or acceptors. For instance, in the case of transition metal oxides such as TiO₂, the dopant species may be oxygen vacancies. For GaN, the dopant species may be nitride vacancies or sulfide ions. For compound semiconductors, the dopants may be n-type or p-type impurities.

The nanoscale switching device 100 can be switched between ON and OFF states by controlling the concentration and distribution of the oxygen vacancies in the switching material in the active region 122. When a DC switching voltage is applied across the top and bottom electrodes 120 and 110, an electric field is created across the active region 122. The switching voltage and current may be supplied by a switching circuit 200. The electric field across the active region 122, if of a sufficient strength and proper polarity, may drive the oxygen vacancies to drift through the switching material towards the top electrode 120, thereby turning the device into an ON state.

By way of example, as shown in FIG. 1, in one embodiment the switching material may be TiO₂. In this case, the dopants that may be carried by and transported through the switching material are oxygen vacancies (V_{O}²⁺). The active region 122 of the switching device has two sub-regions or layers: a primary region 124 and a secondary region 126. The primary region 124 is the main place where the switching behavior occurs. In the originally formed state of the device, the primary region 124 has a relatively low dopant concentration, while the secondary region 126 has a relatively high dopant level. The secondary region 126 functions as a dopant source/drain. During a switching operation, dopants may be driven from the secondary region 126 into the primary region 124, or from the primary region to the secondary region, to change the distribution of dopants in the primary region, thereby changing the conductivity across the primary region.

If the polarity of the electric field is reversed, the dopants may drift in an opposite direction across the switching material and away from the top electrode 120, thereby turning the device into an OFF state. In this way, the switching is reversible and may be repeated. Due to the relatively large electric field needed to cause dopant drifting, after the switching voltage is removed, the locations of the dopants remain stable in the switching material. The switching is bipolar in that voltages of opposite polarities are used to switch the device on and off. The state of the switching device 100 may be read by applying a read voltage to the bottom and top electrodes 110 and 120 to sense the resistance across these two electrodes. The read voltage is typically much lower than the threshold voltage required to induce drifting of the ionic dopants between the top and bottom electrodes, so that the read operation does not alter the resistance state of the switching device.

Memristive switching devices may be formed into an array for various applications that benefit from having a high density of switching devices. FIG. 2 shows an example of a two-dimensional array 160 of memristive switching devices. The array 160 has a first group 161 of generally parallel nanowires 162 running in a first direction, and a second group 163 of generally parallel nanowires 164 running in a second direction at an angle, such as 90 degrees, from the first direction. One group of the nanowires may be labeled as the row lines, and the other group may be labeled as the column lines. The two layers of nanowires 162 and 164 form a two-dimensional lattice which is commonly referred to as a crossbar structure, with each nanowire 162 in the first layer intersecting a plurality of the nanowires 164 of the second layer, and vice versa. A memristive switching device 166 may be formed at each intersection of the nanowires 162 and 164. The switching device 166 has a nanowire of the second group 163 as its top electrode and a nanowire of the first group 161 as the bottom electrode, and an active region 172 containing a switching material between the two nanowires. Each memristive device 166 in the two-dimensional array can be uniquely addressed by selecting the row line and column line that form the electrodes of the memristive device.

As mentioned above, one challenge that results from the use of a crossbar memory structure is that it can be difficult to reliably read the resistance state of a selected device in the array. To sense the resistance state of the selected device, a sensing voltage may be applied to the device via the row line and column line of the device, and the current flowing through the selected device may be monitored to determine the resistance of the device. There are, however, other switching devices connected to the selected row line or the selected column line. Those devices, referred to as “half-selected” devices, can form paths for leakage current, and it can be difficult to isolate the current flowing through the selected device from the leakage current, which can be rather large if there are many devices on each row line or column line.

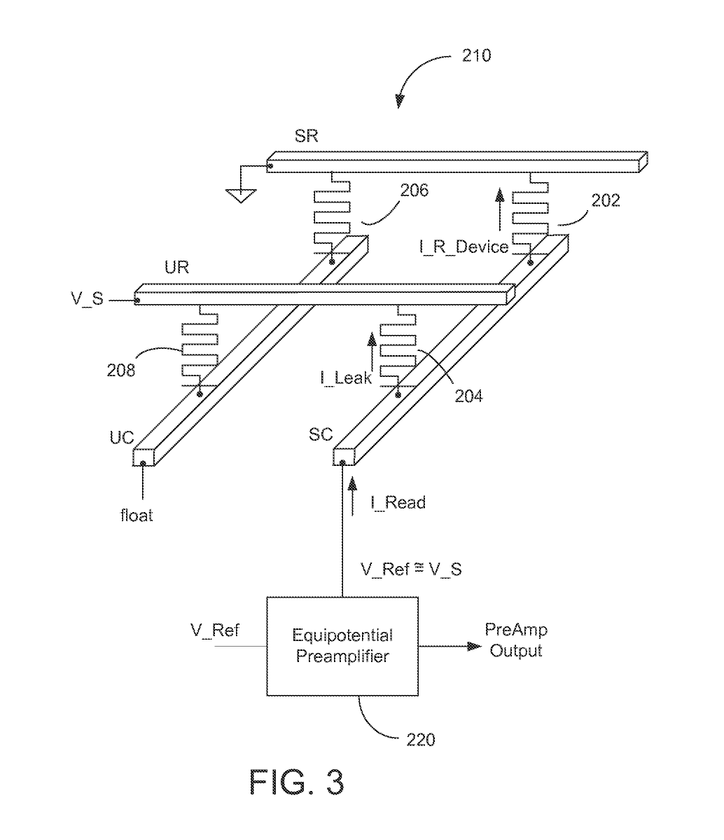

To facilitate a better understanding of the issue of leakage current in a crossbar and how it can complicate the operation of reading a selected resistive switching device (or the “target device”), FIG. 3 shows an abstraction of a crossbar 210 in a simplified form. The target device 202 (shown in electronic circuit symbol of a memristor) to be read is at the intersection of a selected row line SR and a selected column line SC. The unselected row UR in FIG. 3 represents all rows in the crossbar 210 other than the selected row SR, and the unselected column line UC represents all columns of the crossbar 210 other than the selected column line. The device 204 represents all other resistive switching devices connected in parallel to the selected column line SC, and the device 206 represents all other resistive switching devices connected in parallel to the selected row line SR. The device 208 represents all resistive switching devices in the crossbar 210 that are not connected to either the selected column or the selected row. When a read voltage is applied across the selected column SC and the selected row SR, the devices 204 and 206 become half-selected. If there is a voltage difference between the selected row or column line and the unselected lines, the half-selected devices will pass leakage currents due to their finite resistance values. Such leakage currents are a form of noise for the read operation. If there are many switching devices connected to each row or column line in the crossbar, the magnitude of the leakage current can become rather large, and can swamp the real signal of the read operation, which is the current passing through the target device under the read voltage.

An effective solution to the leakage current problem is to bias all the unselected row lines in the crossbar to substantially the same voltage that is applied to the selected column line during the read operation. As illustrated in FIG. 3, when the unselected row line UR is biased to substantially the same voltage as the selected column line, the leakage current passing through the half-selected device 204 will be zero or very small. Thus, the sensing current flowing through the selected column SC can have a very small noise component and be mostly the read current I_R_Device flowing through the target device 202. This approach, termed “equipotential sensing,” provides an effective way to achieve a reasonably high signal/noise ratio for the read operation. To maintain the selected column line SC at substantially the same voltage of the unselected row lines, an equipotential preamplifier 220 may be used. The equipotential preamplifier 220 is connected to the selected column SC, and has a reference voltage input. For the read operation, the reference voltage V_Ref is set to be substantially the same as sense voltage V_S to which the unselected row lines are biased. The equipotential preamplifier holds the selected column line SC to the reference voltage V_Ref while allowing the read current I_Read to flow to the crossbar 210 through the selected column line SC. The effectiveness of the equipotential sensing technique depends on the proper setting of the reference voltage for the equipotential preamplifier. The reference voltage V_Ref is set not only to be close to the biasing voltage V_S on the unselected row lines so as to reduce the leakage current, but also to enable the equipotential preamplifier to operate in a linear range. Moreover, it is desirable to have a convenient and effective way to determine the resistance state of the target device and to indicate the state in an easy-to-read format.

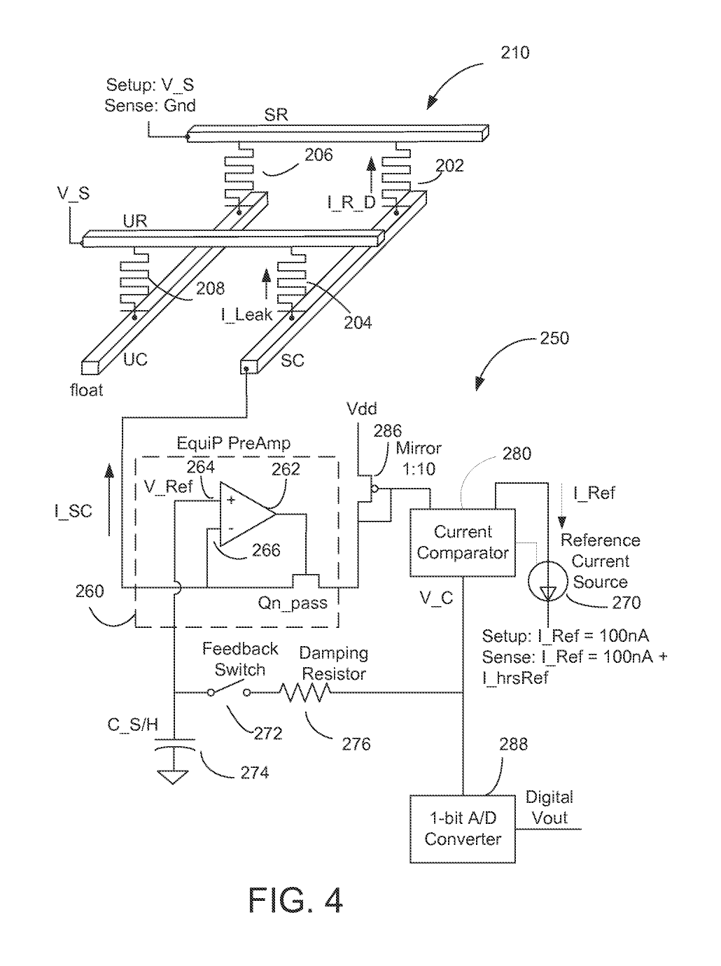

FIG. 4 shows an embodiment of an “equipotential sensing” circuit 250 which includes an equipotential preamplifier 260. The equipotential preamplifier 260 has a buffered direct injection circuit which contains an operational amplifier 262 and a pass transistor Qn_pass. The reference voltage V_Ref goes to the positive input 264 of the operational amplifier 262. The output of the operational amplifier 262 is connected to the gate of the pass transistor Qn_pass, while the negative input 266 of the operational amplifier 262 is connected to the drain side of the pass transistor Qn_pass and to the selected column SC of the array 210. The circuit further includes a reference current source 270 which, as described in greater detail below, may be used in both setting up the reference voltage V_Ref and determining the resistance state of the target device 202 being read.

For setting up the reference voltage V_Ref, the circuit 250 has reference voltage setting components which include a feedback switch 272 and a sample-and-hold capacitor 274. The circuit utilizes feedback to set the reference voltage V_Ref. The feedback path of the circuit includes a current comparator 280, which in general evaluates the current I_SC passed by the equipotential preamplifier 260 against a reference current generated by the reference current source 270. The output of the current comparator 280 may be used in the setup stage as a feedback signal, and may be used in the sensing stage to indicate the resistance state of device being read. Specifically, in the embodiment shown in FIG. 4, the output of the current comparator 280 is a voltage V_C. In the setup stage, the voltage V_C is connected to the positive input of the operational amplifier 262 via a damping resistor 276 and the feedback switch 272, which is closed during the setup operation. The voltage V_C is also connected to an output buffer in the form of a 1-bit analog-to-digital converter 288 so that it drives the output buffer in the sensing stage to provide a digital output (0 or 1) indicating whether the target device is in an ON or OFF state.

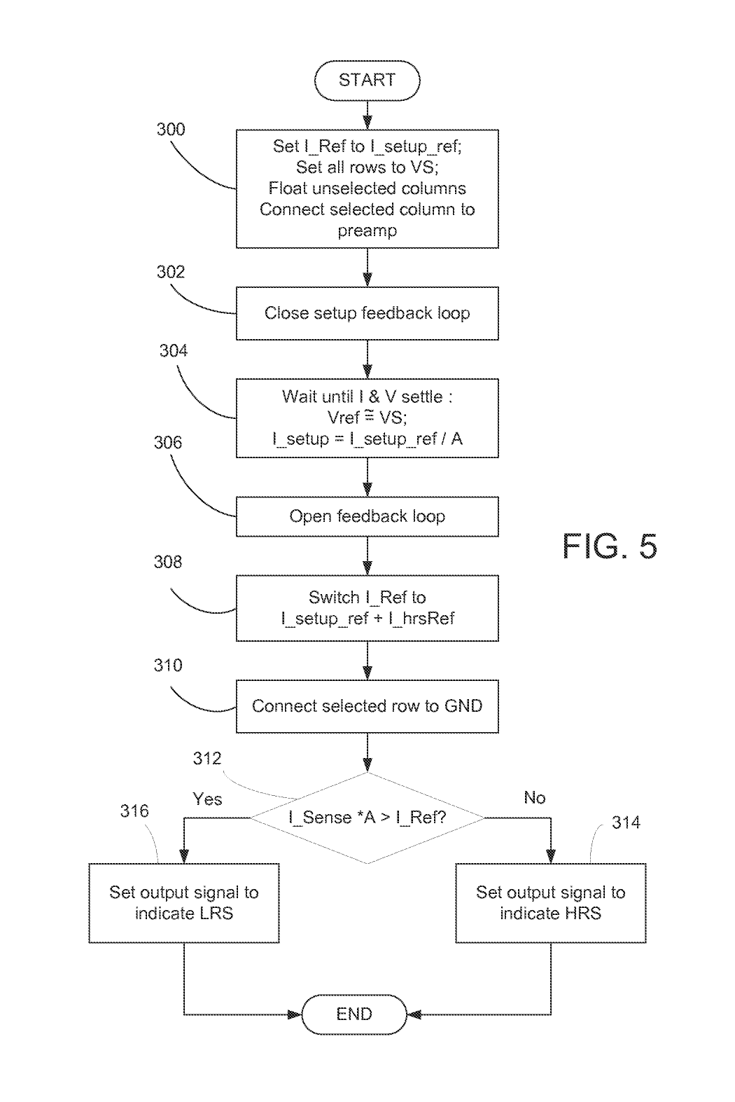

The process of reading the target device 202 in the crossbar 210 using the read circuit 250 is now described with reference to the flowchart in FIG. 5. First, the circuit 250 is initialized for setting up the circuit for the read operation (step 300). To that end, the reference current source 270 is set to provide a setup reference current I_setup_ref. The selected column line SC of the target device 202 to be read is connected to the output of the equipotential preamplifier 260, which is connected to the negative input of the operational amplifier 262. The row lines of the array (SR and UR) are all connected to the read voltage V_S, which may be provided by an external voltage source. All the unselected column lines (UC) are left floating.

Thereafter, the setup operation is carried out by closing the feedback switch 272 to close the feedback loop (step 302). As a result, the output voltage V_C of the current comparator 280 is connected to the positive input 264 of the operational amplifier 262, thereby modifying the output voltage of the operational amplifier 262. This changes the current passing through the transistor Qn_pass, which is controlled by the operational amplifier output. The current passed by the transistor Qn_pass is duplicated by means of a current mirror 286, which in the embodiment also provides current amplification. In the example shown, the amplifying factor A is 10. Thus, the current mirror 286 amplifies the transistor current by ten times before feeding it to the current comparator 280 as one input. The current comparator 280 takes the current passed by the reference current source 270 as a second input. The output voltage V_C of the comparator 280 changes based on the difference between the output of the current mirror 286 and the output of the reference current source 280. The change in V_C is fed back to the operational amplifier 262.

This feedback process is left on for a sufficient time until the voltages and current transients settle (step 304). At the end of this feedback-controlled process, the equipotential preamplifier reference voltage V_Ref on the positive input of the operational amplifier 264 is close to the sense voltage V_S applied to the row lines, but with a slight difference such that the current I_SC flowing to the selected column SC is about the setup reference current I_setup_ref divided by the amplifying factor A of the current mirror 286. By way of example, if I_setup_ref is 100 nA and the amplifying factor A is 10, then the amount of current_I_setup going to the array 210 at the completion of the setup stage will be close to 10 nA. The amplitude of the current I_setup is chosen to be sufficient to ensure that equipotential preamplifier is in its linear operating range, but small enough so that it does not overwhelm the current signal during the read operation, as described below. After the reference voltage V_Ref is set, the feedback loop is opened by opening the switch 272 (step 306). The reference voltage V_Ref is held by the sample-and-hold capacitor 274 and applied to the positive input of the operational amplifier 262.

To initiate the sense operation, the output I_Ref of the reference current source 270 is set to be the sum of I_setup_ref and I_hrsRef (step 308). The current I_hrsRef is a reference for determining whether the target device 202 being read is in the ON or OFF state. It is selected such that its magnitude divided by the amplifying factor A of the current mirror 286 is sufficiently higher than the average amount of current I_hrs_ave a device in the high-resistance state (i.e., OFF state) will pass under the voltage V_S, but sufficiently lower than the average current I_lrs_ave the device will pass in the low-resistance state (i.e., ON state). In other words, I_hrs_ave<I_hrsRef /A<I_lrs_ave.

To carry out the sensing operation, the selected row SC of the target device 202 is connected to the ground potential (step 310). This causes a read current I_R_Device to flow through the target device 202 under the voltage V_Ref held by the equipotential preamplifier 260. The current I_SC now passed by the equipotential preamplifier 260 to the array 210 includes the device current I_R_Device and the bias current I setup set during the setup stage. This sum, referred to as I_Sense, is amplified by the current mirror 286 and sent to the current comparator 280 for comparison. In this example, the amplifying factor is 10, so the current comparator 280 compares I_Sense*10 with I_Ref (step 312). If I_Sense*10 is smaller than I_Ref, the comparator output V_C goes to a value close to Vdd. On the other hand, if I_Sense*10 is larger than I_Ref, then V_C goes to a value close to ground. The voltage V_C is fed to the 1-bit A/D converter 288 to generate a digital output of either 0 or 1. For instance, if V_C is close to Vdd, the converter output has a digital value of 0, indicating that the device is in the high-resistance (OFF) state (step 314). If V_C is close to ground, the converter 288 generates a digital output of 1, indicating that the device is in a low-resistance (ON) state (step 316).

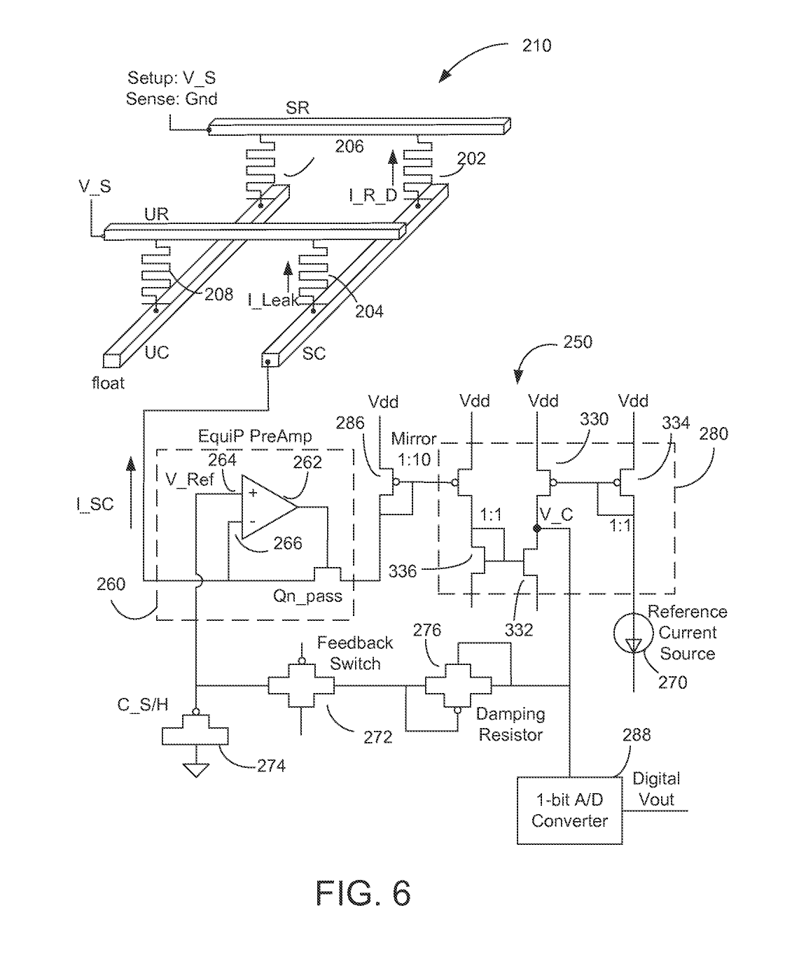

FIG. 6 shows implementation features of some components in the embodiment of the read circuit shown in FIG. 4. These implementation features facilitate the fabrication of the read circuit 250 using semiconductor fabrication techniques. Specifically, the current comparator 280 includes a PMOS transistor 330 and an NMOS transistor 332 connected in series between Vdd and ground. The PMOS transistor 330 forms a current mirror with another transistor 334, which forms one input of the current comparator and is connected to the reference current source 270. The NMOS transistor 332 forms another current mirror with a transistor 336, which forms the other input of the current comparator 280. The output voltage V_C of the current comparator is taken from the junction between the PMOS and NMOS transistors 330 and 332. As described above, the voltage V_C swings either towards Vdd or towards ground, depending on which of two currents being compared is greater.

Also shown in FIG. 6, the sample-and-hold capacitor 274 may be implemented as a PMOS transistor. The drain and source of the transistor are connected together, and the gate is connected to the positive input of the operational amplifier 262. Thus, the capacitance utilized for the sample-and-hold function is the gate capacitance of the transistor. The feedback switch 272 is implemented as a PMOS transistor and an NMOS transistor tied together to form a transmission gate switch. The damping resistor 276 is formed by connecting a PMOS transistor and an NMOS transistor, and with the gate of the PMOS transistor connected to one input and the NMOS transistor connected to the other input. This configuration functions as a non-linear resistor for controlling the stability of the high-gain negative feedback.

In the foregoing description, numerous details are set forth to provide an understanding of the present invention. However, it will be understood by those skilled in the art that the present invention may be practiced without these details. While the invention has been disclosed with respect to a limited number of embodiments, those skilled in the art will appreciate numerous modifications and variations therefrom. It is intended that the appended claims cover such modifications and variations as fall within the true spirit and scope of the invention.

What is claimed is:

1. A read circuit for sensing a resistance state of a resistive switching device in a crosspoint array, comprising:
an equipotential preamplifier for connecting to a selected column line of the resistive switching device in the array to deliver a sense current while maintaining the selected column line at a reference voltage near a biasing voltage applied to unselected row lines of the array;
a reference current source for generating a sense reference current; and
a current comparator connected to evaluate the sense current delivered by the equipotential preamplifier against the sense reference current and generating an output signal indicative of the resistance state of the resistive switching device.

2. A read circuit as in claim 1, further including an output buffer for converting the output signal of the current comparator into a digital output signal.

3. A read circuit as in claim 1, further including setup components for setting the reference voltage of the equipotential preamplifier based on a setup reference current generated by the reference current source.

4. A read circuit as in claim 3, wherein the setup components for setting the reference voltage include a feedback switch for selectively connecting an input of the equipotential preamplifier to an output of the current comparator, and wherein the current comparator is connected to evaluate an output current of the equipotential preamplifier against the setup reference current.

5. A read circuit as in claim 4, wherein the setup components for setting the reference voltage further include a sample-and-hold capacitor connected to the input of the equipotential preamplifier for maintaining the reference voltage.

6. A read circuit as in claim 5, further including a current amplifier for amplifying the output current of the equipotential preamplifier to generate an amplified current as an input to the current comparator.

7. A read circuit as in claim 5, wherein the sample-and-hold capacitor is a gate capacitance of a transistor.

8. A read circuit as in claim 5, wherein the setup components further include a damping resistor formed by tying a PMOS transistor and an NMOS transistor together.

9. A read circuit as in claim 1, wherein the current comparator includes a PMOS transistor and an NMOS transistor connected in series, and the output signal of the current comparator is taken from a junction between the PMOS transistor and the NMOS transistor.

10. A method of reading a resistance state of a resistive switching device in a crosspoint array, comprising:
connecting an equipotential preamplifier to a selected column line of the resistive switching device in the array;
applying a reference voltage to the equipotential preamplifier;
generating, by the equipotential preamplifier, a sense current flowing to the selected column line while biasing the selected column line to the reference voltage;
evaluating the sense current against a sense reference current; and
generating a read output signal indicating the resistance state of the resistive switching device.

11. A method as in claim 10, wherein the step of generating the read output signal includes converting a current comparison signal generated by the evaluation step into a digital signal.

12. A method as in claim 10, wherein the step of evaluating includes amplifying the sense current to generate an amplified current, and comparing the amplified current with the sense reference current.

13. A method as in claim 10, wherein the step of generating the sense current includes connecting a selected row line of the resistive switching device to ground.

14. A method as in claim 10, wherein the step of applying a reference voltage includes:
providing a setup reference current;
evaluating a setup current generated by the equipotential preamplifier against the setup reference current to provide a current comparison output voltage, and
feeding the current comparison output voltage back to an input of the equipotential preamplifier until a voltage at the input of the equipotential preamplifier settles to form the reference voltage and the setup current generated by the equipotential preamplifier reaches a value set according to the setup reference current.

15. A method as in claim 14, further including the step of sampling and holding the reference voltage using a capacitor connected to the input of the equipotential preamplifier.
